(19) United States
(12) Patent Application Publication
(10) Pub. No.: US 2010/0164089 A1
(43) Pub. Date: Jul. 1, 2010

(54) Non-Conductive Planarization of Substrate Surface for Mold Cap

(75) Inventor: Gene Felten, Prunedale, CA (US)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/278,653

(22) PCT Filed: Feb. 14, 2007
(86) PCT No.: PCT/IB07/50490

§ 371 Date: Aug. 7, 2008

Related U.S. Application Data
(60) Provisional application No. 60/774,119, filed on Feb. 15, 2006.

(51) Int. Cl. H01L 23/48; H01L 21/56; H05K 1/00

(52) U.S. Cl. 257/692; 438/124; 174/250; 257/E21.502; 257/E23.01; 257/E23.116

(57) ABSTRACT

Consistent with an example embodiment, there is a method for fabricating a semiconductor package having a substrate. The method comprises defining an encapsulation boundary on a surface of the substrate; the encapsulation boundary is divided into a molding region and a non-molding region. Over the substrate, a plurality of conductive traces is provided. Each conductive trace has an inner connection located in the molding region and an outer connection located in the non-molding region. A plurality of non-conducting dummy traces across the encapsulation boundary is provided. The plurality of non-conductive dummy traces are interposed among the conductive traces and are spaced apart at an interval less than a predetermined minimum air-vein forming distance (Dmln). A solder mask over the substrate covers the conductive traces and the non-conductive dummy traces. The molding region of the substrate is encapsulated with a molding compound.

The invention relates to integrated circuit (IC) packaging. More particularly this invention relates to assembling an IC device on a laminated substrate in which the surface of the substrate is planarized to provide a surface for application of a solder mask upon the substrate.

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

Many varieties of semiconductor devices have been manufactured with various applications in numerous disciplines. Such silicon-based semiconductor devices often include metal-oxide-semiconductor field-effect transistors (MOSFET), such as p-channel MOS (PMOS), n-channel MOS (NMOS) and complementary MOS (CMOS) transistors, bipolar transistors, BiCMOS transistors. Such MOSFET devices include an insulating material between a conductive gate and silicon-like substrate; therefore, these devices are generally referred to as IGFETs (insulated-gate FET).

Each of these semiconductor devices generally includes a semiconductor substrate on which a number of active devices are formed. The particular structure of a given active device can vary between device types. For example, in MOS transistors, an active device generally includes source and drain regions and a gate electrode that modulates current between the source/drain regions.

Furthermore, such devices may be digital or analog devices produced in a number of wafer fabrication processes, for example, CMOS, BiCMOS, Bipolar, etc. The substrates may be silicon, gallium arsenide (GaAs) or other substrate suitable for building microelectronic circuits thereon.

After undergoing the process of fabrication, the silicon wafer has a predetermined number of devices. These devices are tested. Good devices are collected and packaged.

The packaging of complex IC devices is increasingly playing a role in its ultimate performance. In particular, laminated substrates provide a base for an IC device. The IC device is encapsulated in a molding compound. For an encapsulated package, the design of laminated substrate packages for IC devices involves careful attention to electrical performance parameters based on the geometry of the artwork and the properties of the materials used. Also, the substrate layout must accommodate good yield in the assembly of the device. For these reasons, design rules for the various geometries and assembly processes must be adhered to in the design process. The specifications for the assembly of the devices are provided by the assembly subcontractor, such as minimum and maximum wire length, clearance from metal wire bonding area to the edge of the IC die, clearance from the metal wire bonding area to the edge of the plastic encapsulation area, etc.

The substrate layout is designed based on the substrate manufacturing design rules and also on good design practices which are known to enhance the performance requirements of the device. An electrical model is generated and simulation is performed to verify that the targeted performance criteria is met in the design layout. If the design layout meets the performance criteria as indicated by electrical simulation, the artwork for the design is delivered to the assembly contractor for final review and tooling.

In an effort to increase the assembly yield, an assembly subcontractor may make changes to the design, and these changes may alter the performance of the device. The particular case being addressed here involves the assembly contractor adding metal patterns to the outer surface of the substrate in areas having low metal pattern density near the plastic encapsulation outline. The additional metal pattern assures that the surface of the substrate is flat, or planar, thus reducing the risk of “air veins” or paths where blowout of molding compound can occur between the substrate and the mold.

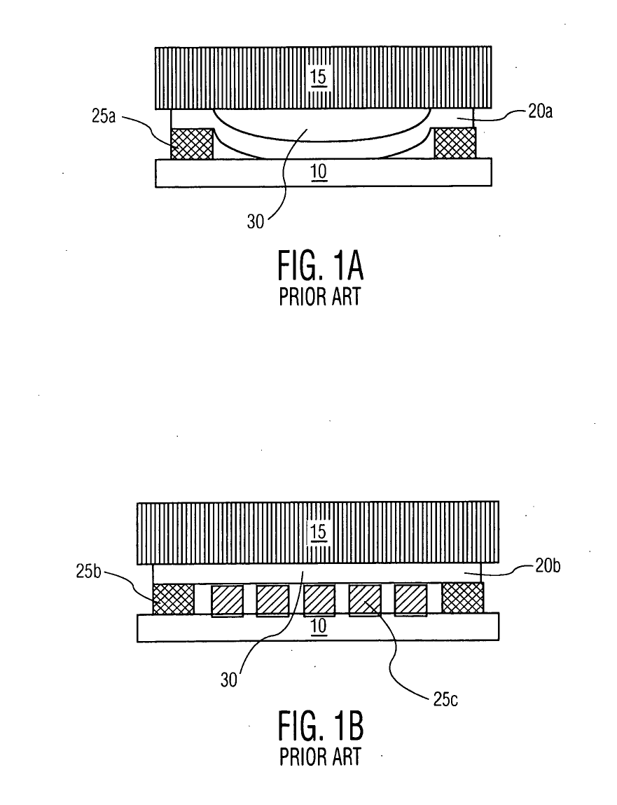

Refer to FIG. 1A. In an example substrate assembly, a laminate substrate 10 has sparse metal pattern 25a. Upon the metal pattern 25a, a solder mask 20a is applied. The non-planarity of the solder mask 20a may result in an air vein 30 which results in mold compound blowout after encapsulation 15.

Refer to FIG. 1B. In another example substrate assembly, the structure of FIG. 1A is modified to add metallization 25c to the sparse metal pattern 25b. Solder mask 20b is applied to a more planar surface. Encapsulation does not cause the formation of air vein 30. Such a method may be found in US Patent Application US 2003/0040431 A1 titled, “Method of Fabrication a Substrate-Based Semiconductor Package without Mold Flash,” incorporated by reference in its entirety.

In addressing the planarity or the metal patterns, a situation may occur when the changes made by the assembly contractor adversely affect the electrical performance of the device. The contributions of the metal pattern change the signal properties of resistance, capacitance and inductance. Often, the IC package designer is not notified that a change has been made to the artwork. Also the designer may not be provided a copy of the modified design. Therefore, the designer does not have the opportunity to generate a new model of the substrate layout so that he can perform a new simulation. Furthermore, the end user of the packaged IC device is not aware that the simulation results they have been supplied do not match the actual device he is buying.

There is a need to address the challenge of assuring planarity of the solder mask in a laminated substrate package to prevent the formation of air vanes during encapsulation, yet without creating undesirable electrical effects due to the addition of metallization near critical signal traces.

The present invention has been found useful in implementing a change to the process of substrate manufacturing. Rather than smoothing the surface of the laminate substrate by adding metal patterns, a non-electrically conductive material may be applied to assure a flat surface, and thus prevent “air veins” from forming during the encapsulation process. By using a non-electrically conductive material, the electrical performance is not adversely affected. A new model and simulation need not be generated, and the customer does not receive devices that have been altered since receiving the simulation data for substrate design.

In an example embodiment, there is a method for fabricating a semiconductor package having a substrate. The method comprises defining an encapsulation boundary on a surface of the substrate; the encapsulation boundary is divided into a molding region and a non-molding region. Over the substrate, a plurality of conductive traces is provided. Each conductive trace has an inner connection located in the molding region and an outer connection located in the non-molding region. A plurality of non-conducting dummy traces across the encapsulation boundary is provided. The plurality of non-conducting dummy traces are interposed among the conductive traces and are spaced apart at an interval less than a predetermined minimum air-vein forming distance (Dₘᵢₙ). A solder mask over the substrate covers the conductive traces and the non-conductive dummy traces. The molding region of the substrate is encapsulated with a molding compound.

In another example embodiment, there is an integrated circuit (IC) device that comprises, an IC die mounted in a die attach area in a laminate substrate; the laminate substrate has a surface divided into an area inside an encapsulation boundary region and an area outside the encapsulation boundary region; the die attach area is within the area inside the encapsulation boundary. The IC die is encapsulated with a molding compound within the encapsulation boundary region. The laminate material has a top metal layer of conductive traces of a predetermined vertical thickness; the conductive traces are in a predetermined arrangement having dense regions and sparse regions. The sparse regions of adjacent conductive traces are spaced apart at an interval greater than a predetermined minimum air-vein forming distance (Dₘᵢₙ). Each conductive trace has an inner connection located inside the encapsulation boundary region and an outer connection located outside the encapsulation boundary region. The inner connection of each conductive trace connects the IC die at predefined pads. A non-conducting material is interspersed as dummy traces between the sparse regions of conductive traces across the encapsulation boundary region; the dummy traces have a thickness comparable to the vertical thickness of the conductive traces. The dummy traces provide a planar surface and reduce spacing between features to an interval less than the predetermined minimum air-vein forming distance (Dₘᵢₙ).

The above summary of the present invention is not intended to represent each disclosed embodiment, or every aspect, of the present invention. Other aspects and example embodiments are provided in the figures and the detailed description that follows.

The invention may be more completely understood in consideration of the following detailed description of various embodiments of the invention in connection with the accompanying drawings, in which:

FIG. 1A (Prior Art) is a cross-section of encapsulation of a substrate depicting the “air vein” in which blow out of molding material owing to deflection of the solder mask may occur;

FIG. 1B (Prior Art) is a cross-section of additional metallization for planarizing the underlying surface upon which the solder mask is applied;

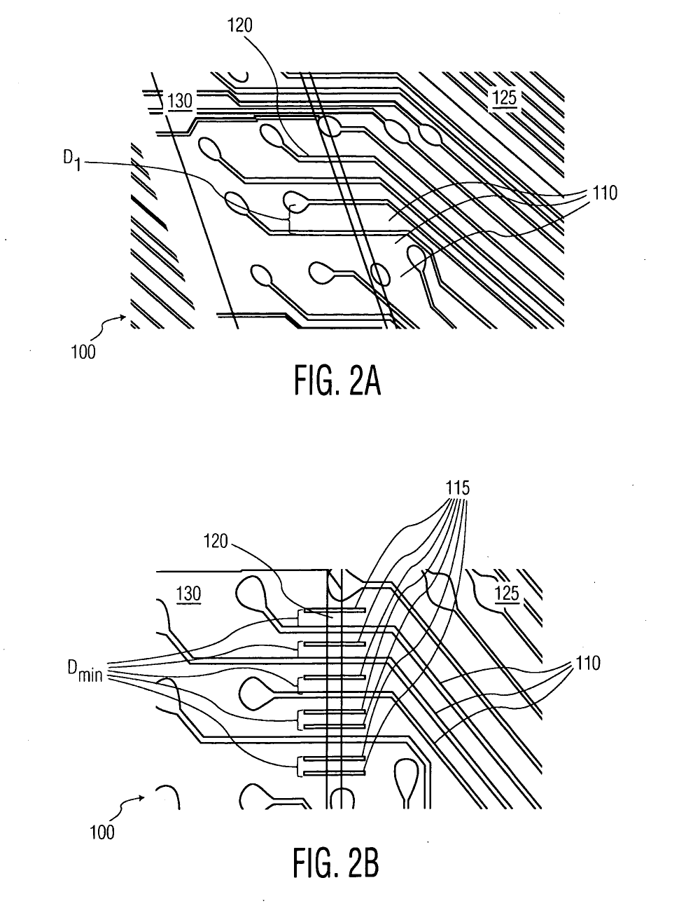

FIG. 2A is a top view of an example layout of electrical traces spaced apart to enhance electrical (capacitive) isolation;

FIG. 2B is a top view of an example layout of electrical traces with the addition of dummy traces at mold cap edge to prevent mold flash in according to an embodiment of the present invention; and

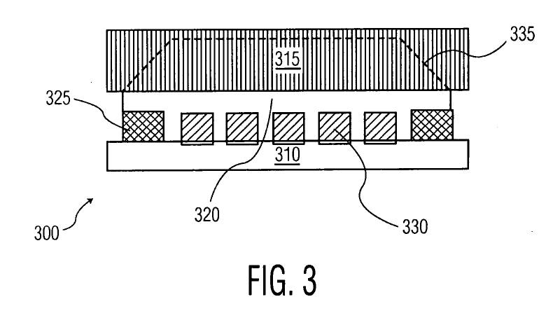

FIG. 3 is a cross-section depicting using non-conductive planarization material upon which the solder mask is applied according to an embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

The present invention has been found to be useful in the encapsulation of IC devices. During encapsulation, there is a possibility that molding compound may flash out beyond the boundary defined by the mold cap in areas with sparsely-spaced pairs of conductive traces.

In addressing this problem, the invention provides for one or more dummy traces of non-conductive material to be placed between sparsely spaced pairs of conductive traces (at some distance D₁ between them). The dummy traces are interposed among those electrically conductive traces that are spaced at an interval greater than a predetermined minimum flash-causing distance Dₘᵢₙ, that has been determined cause mold flash across the mold cap boundary. In an example process, the predetermined minimum flash-causing distance Dₘᵢₙ is preferably not greater than 0.9 mm, and more preferably not greater than 0.5 mm. In the circuit layout design, if any neighboring pair of electrically conductive traces are spaced larger than this minimum flash-causing distance Dₘᵢₙ across the mold cap boundary, then one or more dummy traces are interposed among them. The particular Dₘᵢₙ is dependent upon the given characteristics of the molding compound used. In practice, these dummy traces can be added after the metallization traces defined on the laminate. Furthermore, a solder mask may be added to fill in the spaces among the dummy traces, as well.

Refer to FIG. 2A. In an example embodiment, a laminate substrate 100 has conductive traces 110. The mold cap boundary 120 surrounds a region in which the IC device die is mounted. The spaces between the conductive traces 110 may exceed Dₘᵢₙ. Within mold cap boundary 120, the region in which the IC device is mounted is defined as a molding region 125, a non-molding region 130 is outside of the mold cap boundary 120.

Refer to FIG. 2B. In the laminate substrate 100, dummy traces of non-conductive material 115 are interspersed among the conductive traces so as to render the spacing between features less than Dₘᵢₙ and make the surface of the laminate substrate 100 more planar.

Refer to FIG. 3. An IC package 300 has a laminate 300 with metallization traces 325 spaced at a greater distance than Dₘᵢₙ. Non-conductive dummy traces 330 are inserted between the metallization traces 325. A solder mask 320 is applied over the metallization traces 325 and non-conductive dummy traces 330. Mold cap 315 rests upon a now-planar surface. Since the distance between features is less than Dₘᵢₙ, the likelihood of mold flash is reduced. An example configuration of the shape of the molding compound is shown with dashed lines 335.

While the present invention has been described with reference to several particular example embodiments, those skilled in the art will recognize that many changes may be made thereto without departing from the spirit and scope of the present invention, which is set forth in the following claims.

1. A method for fabricating a semiconductor package having a substrate, the method comprising:
defining an encapsulation boundary on a surface of the substrate, the encapsulation boundary divided into a molding region and a non-molding region;
providing a plurality of conductive traces over the substrate, each conductive trace having an inner connection located in the molding region and an outer connection located in the non-molding region;
providing a plurality of non-conducting dummy traces across the encapsulation boundary, the plurality of dummy traces interposed among the conductive traces that are spaced apart at an interval greater than a predetermined minimum air-vein forming distance;
providing a solder mask over the substrate covering the conductive traces and the non-conductive dummy traces; and
encapsulating the molding region of substrate with a molding compound.

2. The method as recited in claim 1, wherein the predetermined minimum air-vein forming distance is less than about 0.9 mm.

3. The method as recited in claim 1, wherein the predetermined minimum air-vein form distance is less than about 0.5 mm.

4. A packaging substrate having a substantially planar surface, the substrate comprising:
a laminate material having a top metal layer of conductive traces of a predetermined vertical thickness, the conductive traces in a predetermined arrangement having dense regions and sparse regions of conductive traces, the sparse regions of adjacent conductive traces spaced apart a an interval greater than a predetermined minimum air-vein forming distance;
a non-conducting material interspersed as dummy traces between the sparse regions of conductive traces, the dummy traces having a thickness comparable to the vertical thickness of the conductive traces, the dummy traces providing a planar surface and reducing spacing between features to an interval less than the predetermined minimum air-vein forming distance; and
a solder mask applied over the substrate to cover the top metal layer and non-conducting material.

5. The IC substrate as recited in claim 4, wherein the solder mask is the same material as the non-conducting material.

6. An integrated circuit device device comprising:
an IC die mounted in a die attach area in a laminate substrate, the laminate substrate having a surface divided into a area inside an encapsulation boundary region and an area outside the encapsulation boundary region, the die attach area within the area inside the encapsulation boundary, the IC die encapsulated with a molding compound within the encapsulation boundary region;
the laminate material having a top metal layer of conductive traces of a predetermined vertical thickness, the conductive traces in a predetermined arrangement having dense regions and sparse regions of conductive traces, the sparse regions of adjacent conductive traces spaced apart at an interval greater than a predetermined minimum air-vein forming distance, each conductive trace having an inner connection located inside the encapsulation boundary and an outer connection located outside the encapsulation boundary region, the inner connection of each conductive trace connecting the IC die at predefined pads; and
a non-conducting material interspersed as dummy traces between the sparse regions of conductive traces across the encapsulation boundary region, the dummy traces having a thickness comparable to the vertical thickness of the conductive traces, the dummy traces providing a planar surface and reducing spacing between features to an interval less than the predetermined minimum air-vein forming distance.

7. The IC device as recited in claim 6, wherein a solder mask is deposited on the surface of the laminate substrate.
